(19) United States
(12) Patent Application Publication
(10) Pub. No.: US 2010/0213621 A1
(43) Pub. Date: Aug. 26, 2010

(54) Moisture-proof device, moisture-proof IC, and method for increasing moisture-proof capability of IC

(76) Inventors: Wei-Chung Sun, Taipei City (TW); Chin-Ming Lin, Miaoli County (TW); Wei-Jen Chen, Kaohsiung County (TW); Chin-Feng Wu, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/690,902

(22) Filed: Jan. 20, 2010

(30) Foreign Application Priority Data
Feb. 23, 2009 (TW) 098105613

(51) Int. Cl. H01L 23/28; H01L 21/56

(52) U.S. Cl. 257/787; 438/127; 257/E23.116; 257/E21.502

(57) ABSTRACT

Method for increasing the moisture-proof capability of a chip includes coating moisture-proof glue at the chink of the chip. More particularly, when the packaging structure carries a chink exposed to outside of the chip, the chink is coated with the moisture-proof glue for preventing moisture from entering the internal part of the chip so as to increase the moisture-proof capability of the chip.

### BACKGROUND OF THE INVENTION

1. Field of the Invention

The present invention relates to a moisture-proof technology, and more particularly, to a moisture-proof technology for an Integrated Chip (IC).

2. Description of the Prior Art

Please refer to FIG. 1. FIG. 1 is a diagram illustrating a conventional IC 100. The IC 100 is packaged by Ball Grid Array (BGA). The IC 100 comprises a first packaging body 110, a second packaging body 120, and a die 130. The first packaging body 110 is utilized as a molding compound, which protects the die 130; the second packaging body 120 is utilized as a substrate, and the bottom surface of the second packaging body 120 is planted with solder balls, so that the IC 100 is capable of connecting to a Print Circuit Board (PCB) through the solder balls. In this way, the die 130 can communicate with circuitry of the PCB through the second packaging body 120 and the solder balls B. Furthermore, the second packaging body 120 carries the die 130.

The material of the first packaging body 110 can be, e.g. epoxy; the material of the second packaging body 120 can be, e.g. Flame retardant 4 (FR-4). Since the first and the second packaging bodies 110 and 120 are made of different materials, an interface 140 exists between the first and the second packaging bodies 110 and 120 after the first and the second packaging bodies 110 and 120 are combined by the packaging process. Chinks possibly exist at the interface 140 in such structure, which allows moisture to enter the IC 100. In this way, the lifetime and the reliability of the IC 100 are reduced, causing great inconvenience.

### SUMMARY OF THE INVENTION

The present invention provides a moisture-proof device for an Integrated Chip (IC) for increasing moisture-proof capability of the IC. The IC has a first and a second packaging bodies. The moisture-proof device comprises a moisture-proof glue, applied to the first and the second packaging bodies for increasing the moisture-proof capability of the IC.

The present invention further provides a moisture-proof IC. The moisture-proof IC comprises a die; a first packaging body on the die; a second packaging body below the die; and a moisture-proof device, comprising a moisture-proof glue, applied to the first and the second packaging bodies for increasing the moisture-proof capability of the IC.

The present invention further provides a method for increasing moisture-proof capability of an IC. The method comprises applying moisture-proof glue to periphery of the IC.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conventional IC.

FIG. 2 is a diagram illustrating a moisture-proof IC according to a first embodiment of the present invention.

FIGS. 3, 4, and 5 are diagrams illustrating top view, bottom view, and 3-D view of the moisture-proof IC of the first embodiment of the present invention.

FIG. 6 is a diagram illustrating a moisture-proof IC according to a second embodiment of the present invention.

FIGS. 7, 8, and 9 are diagrams illustrating top view, bottom view, and 3-D view of the moisture-proof IC of the second embodiment of the present invention.

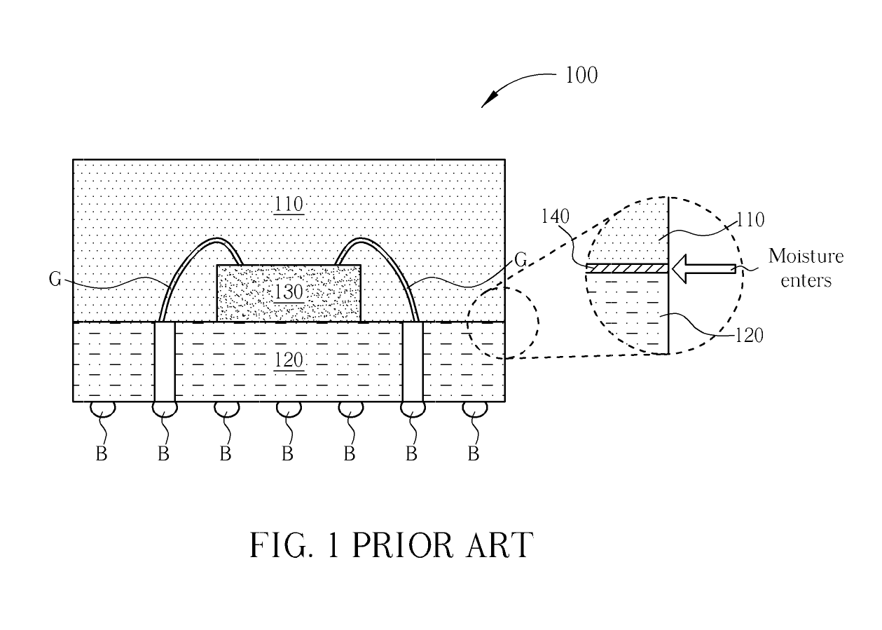

### DETAILED DESCRIPTION

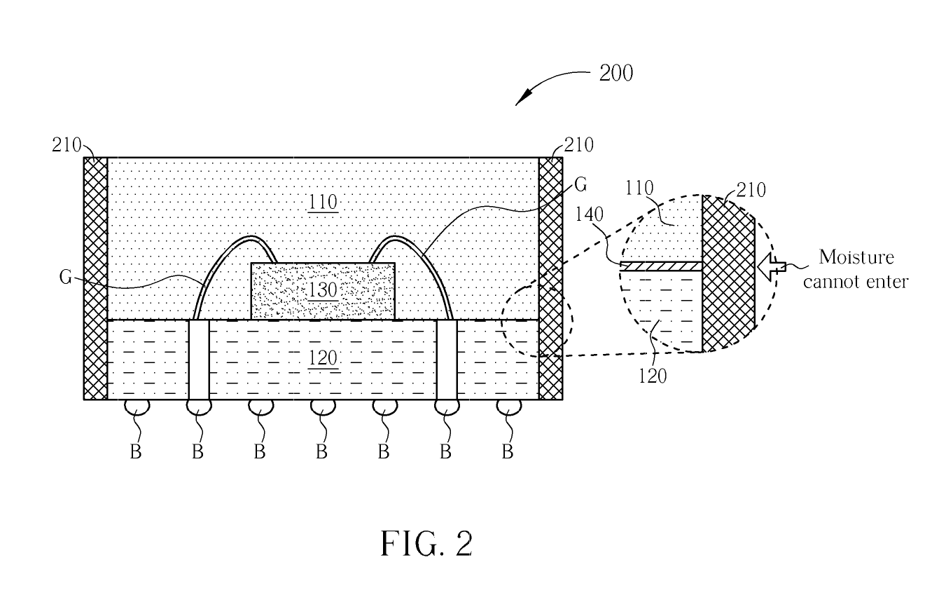

Please refer to FIG. 2. FIG. 2 is a diagram illustrating a moisture-proof IC 200 according to a first embodiment of the present invention. In FIG. 2, the present invention coats moisture-proof glue 210 externally onto the IC 200 for moisture-proof functioning. More particularly, the moisture-proof glue 210 is coated around the periphery of the IC 200. The material of the moisture-proof glue 210 can be, e.g. silicone in solvent, or epoxy. As shown in FIG. 2, the chinks between the first and the second packaging bodies 110 and 120 are covered by the moisture-proof glue 210. It can be clearly seen from FIG. 2 that an interface is formed at the sides of the first and the second packaging bodies 110 and 120, and the moisture-proof glue 120 is applied onto the interface. In this way, moisture cannot enter the IC 200 through the chinks between the first and the second packaging bodies 110 and 120 and cannot damage the IC 200, which increases the lifetime and the reliability of the IC 200.

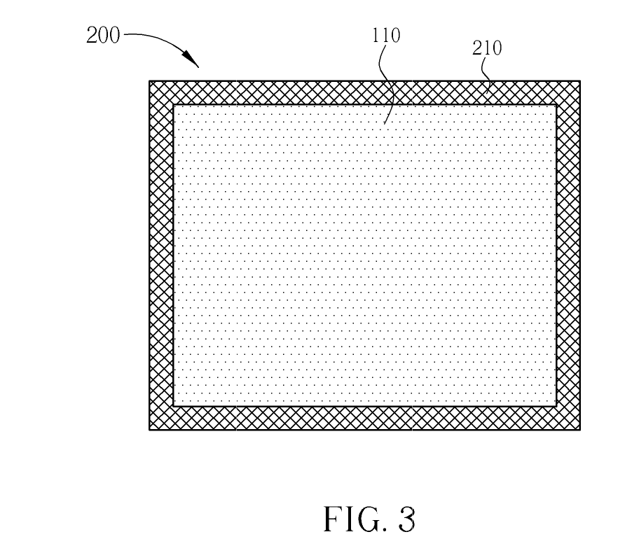

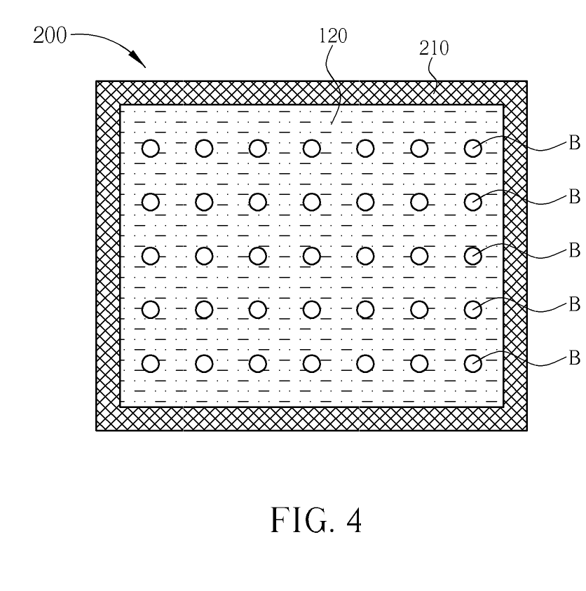

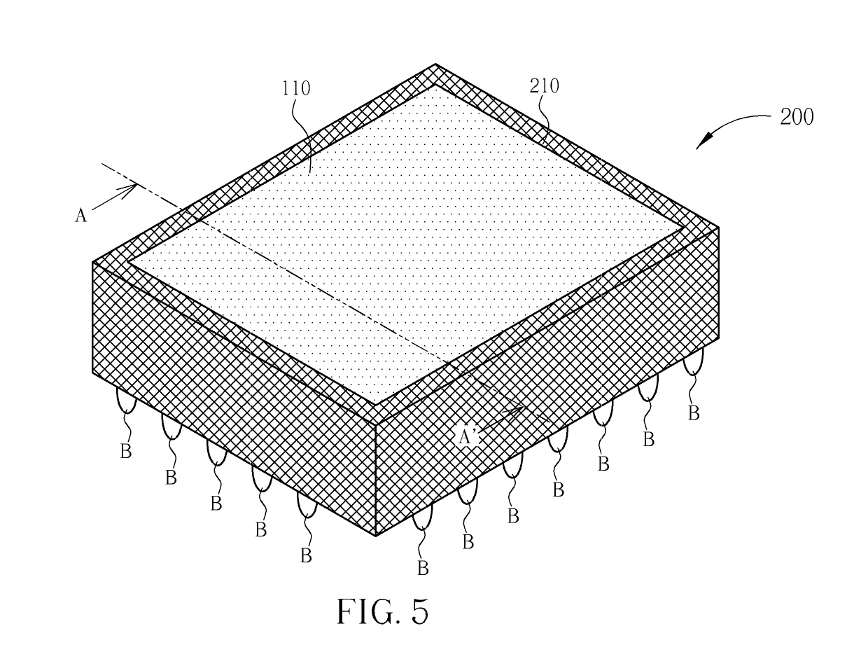

Please refer to FIGS. 3, 4, and 5. FIGS. 3, 4, and 5 are diagrams illustrating top view, bottom view, and 3-D view of the moisture-proof IC 200 of the first embodiment of the present invention. As shown in FIGS. 3, 4, and 5, it can be seen that the moisture-proof glue 210 are applied at the periphery of the IC 200 for moisture-proof. Besides, the cross section cut by the broken line A-A′ in FIG. 5 is FIG. 2.

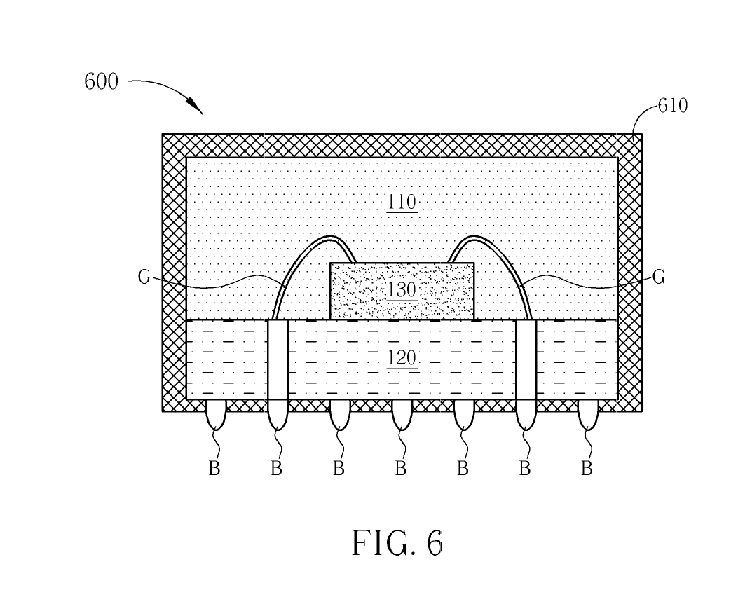

Please refer to FIG. 6. FIG. 6 is a diagram illustrating a moisture-proof IC 600 according to a second embodiment of the present invention. In FIG. 6, the present invention coats moisture-proof glue 610 externally onto the IC 600 for moisture-proof functioning. More particularly, the moisture-proof glue 610 is coated around the periphery, the top surface, and the bottom surface of the IC 600. The material of the moisture-proof glue 610 can be, e.g. silicone in solvent, or epoxy. As shown in FIG. 2, the chinks between the first and the second packaging bodies 110 and 120 are covered by the moisture-proof glue 610, and furthermore, the moisture-proof glue 610 extends to the top surface of the first packaging body 110 and the bottom surface of the second packaging body 120 for increasing the capability of moisture-proof more. Besides, it is noticeable that since the bottom surface of the second packaging body 120 is utilized for planting solder balls B, therefore when the present invention applies the moisture-proof glue 610 to the bottom surface of the second packaging body 120, the present invention avoids applying the moisture-proof glue 610 to the solder balls B so as to prevent the IC 200 from being unable to connect to the PCB. In other words, the bottom surface of the second packaging body 120 comprises solder-ball-planting area and non-solder-ball-planting area, and the solder-ball-planting area is utilized for planting solder balls. Thus the moisture-proof glue 610 is only applied to the non-solder-ball-planting area of the bottom surface of the second packaging body.

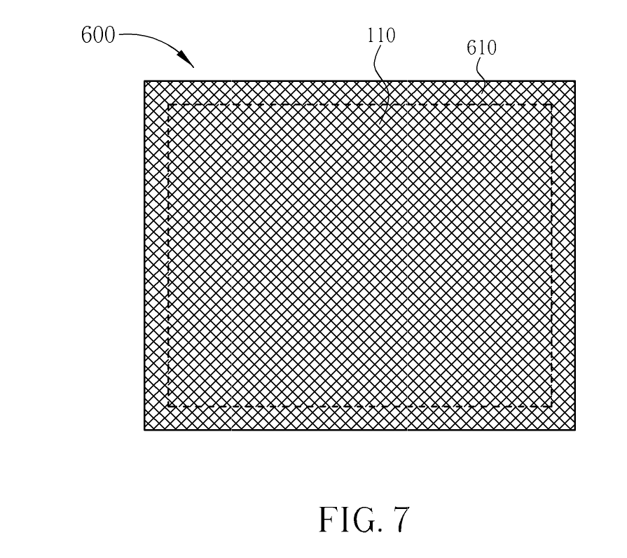

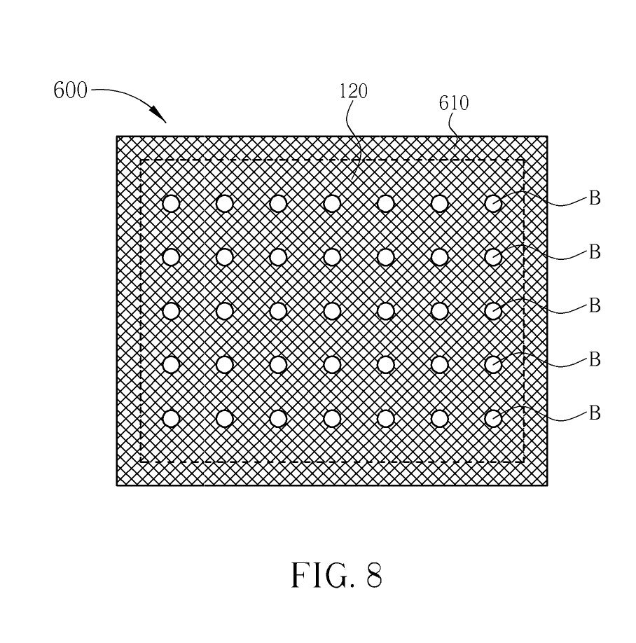

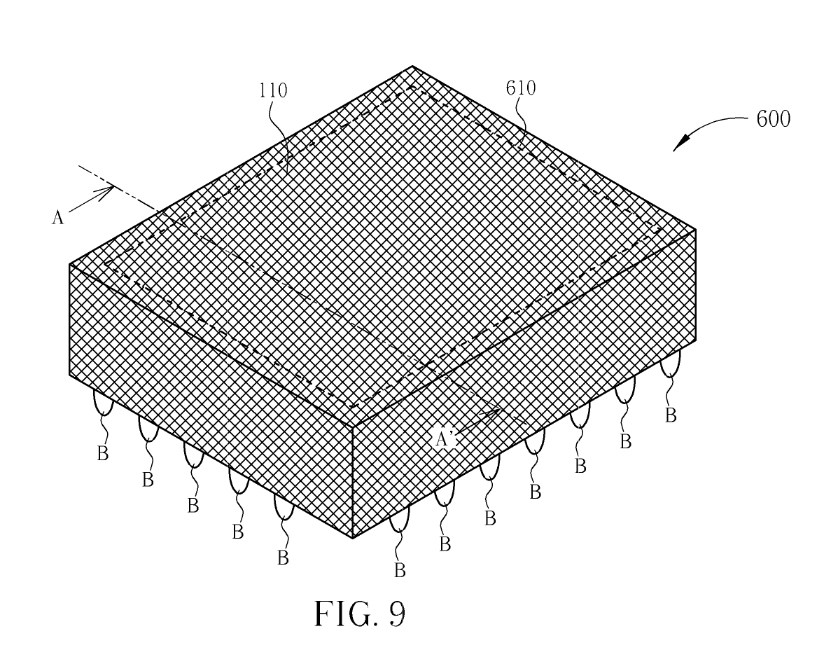

Please refer to FIGS. 7, 8, and 9. FIGS. 7, 8, and 9 are diagrams illustrating top view, bottom view, and 3-D view of the moisture-proof IC 600 of the second embodiment of the present invention. As shown in FIGS. 7, 8, and 9, it can be seen that the moisture-proof glue 210 are applied at the periphery, the top surface, and the bottom surface of the IC 200 for moisture-proof. Besides, the cross section cut by the broken line A-A′ in FIG. 9 is FIG. 6.

Additionally, the materials of the first and the second packaging bodies described in the present invention do not have to be different. That is, the first and the second packaging bodies are determined by the existence of the interface. In other words, even the first and the second packaging bodies are made of the same material, as long as an interface exist, the first and the second packaging bodies are still determined to be different by the present invention.

From the above-mentioned description, it is known that the spirit of the present invention is to apply moisture-proof glue to ICs having interfaces exposed externally for isolating moisture from internal parts of ICs, which avoids conductivities of dies, wires being deteriorated, or the reliability being reduced. The areas the moisture-proof glue mainly applied are the interfaces, of the IC, exposed externally, which are possibly chinks. Moreover, the moisture-proof glue can be applied widely to other areas such as the top surface or the bottom surface of the IC while some particular area, e.g. the area the IC connecting to the external circuitry, has to be avoided to be applied, in order not to cause bad connections. In this way, the moisture-proof capability of IC can be improved. Therefore, the present invention can be applied to any packaging structures having chinks but not limited to BGA packaging structure.

To sum up, by the moisture-proof technology provided by the present invention, moisture is effectively isolated from the internal part of the IC, which increases the moisture-proof capability of the IC, providing great convenience.

Those skilled in the art will readily observe that numerous modifications and alterations of the device and method may be made while retaining the teachings of the invention.

What is claimed is:

1. A moisture-proof device for an Integrated Chip (IC), for increasing moisture-proof capability of the IC, the IC having a first and a second packaging bodies, the moisture-proof device comprising:
a moisture-proof glue, applied to the first and the second packaging bodies for increasing the moisture-proof capability of the IC.

2. The moisture-proof device of claim 1, wherein the moisture-proof glue comprises silicone in solvent or epoxy.

3. The moisture-proof device of claim 1, wherein the first packaging body comprises a first side and the second packaging body comprises a second side, an interface is formed between the first side and the second side, and the moisture-proof glue is applied to the interface.

4. The moisture-proof device of claim 3, wherein the moisture-proof glue is applied to periphery of the IC.

5. The moisture-proof device of claim 4, wherein the moisture-proof glue is further applied to a top surface of the first packaging body and a bottom surface of the second packaging body.

6. The moisture-proof device of claim 5, wherein the first packaging body may be molding compound for protecting internal components of the IC; the bottom surface of the second packaging body comprises a solder-ball-planting area and a non-solder-ball-planting area, and the solder-ball-planting area is utilized for planting solder balls.

7. The moisture-proof device of claim 6, wherein the moisture-proof glue is applied to the non-solder-ball-planting area of the bottom surface.

8. A moisture-proof IC, comprising:
a die;
a first packaging body on the die;
a second packaging body below the die; and
a moisture-proof device, comprising:
a moisture-proof glue, applied to the first and the second packaging bodies for increasing the moisture-proof capability of the IC.

9. The moisture-proof IC of claim 8, wherein the moisture-proof glue comprises silicone in solvent or epoxy.

10. The moisture-proof IC of claim 8, wherein the first packaging body comprises a first side and the second packaging body comprises a second side, an interface is formed between the first side and the second side, and the moisture-proof glue is applied to the interface.

11. The moisture-proof IC of claim 10, wherein the moisture-proof glue is applied to periphery of the IC.

12. The moisture-proof IC of claim 11, wherein the moisture-proof glue is further applied to a top surface of the first packaging body and a bottom surface of the second packaging body.

13. The moisture-proof IC of claim 12, wherein the first packaging body may be molding compound for protecting internal components of the IC; the bottom surface of the second packaging body comprises a solder-ball-planting area and a non-solder-ball-planting area, and the solder-ball-planting area is utilized for planting solder balls.

14. The moisture-proof IC of claim 13, wherein the moisture-proof glue is applied to the non-solder-ball-planting area of the bottom surface.

15. The moisture-proof IC of claim 13, wherein the first packaging body may be epoxy; the second packaging body may be Frame Retardant 4 (FR-4).

16. A method for increasing moisture-proof capability of an IC, comprising: applying moisture-proof glue to periphery of the IC.

17. The method of claim 16, wherein applying the moisture-proof glue to periphery of the IC comprises:
applying the moisture-proof glue to a chink generated by structure of the IC.

18. The method of claim 17, wherein applying the moisture-proof glue to the chink generated by the structure of the IC comprises:
applying the moisture-proof glue to an interface formed by a first side of the first packaging body of the IC and a second side of the second packaging body of the IC.

19. The method of claim 18, further comprising:
applying the moisture-proof glue to a top surface of the first packaging body and a bottom surface of the second body;
wherein the first packaging body may be molding compound; the bottom surface of the second packaging body comprises a solder-ball-planting area and a non-solder-ball-planting area, and the solder-ball-planting area is utilized for planting solder balls.
